(19) United States
(12) Patent Application Publication
(10) Pub. No.: US 2025/0089207 A1
(43) Pub. Date: Mar. 13, 2025

(54) CIRCULATING SUBMERGED LIQUID COOLING CABINET

(71) Applicant: Hebei Qinhuai Data Co., Limited., Zhangjiakou City (CN)

(72) Inventor: Binghua ZHANG, Zhangjiakou City (CN)

(21) Appl. No.: 18/817,008

(22) Filed: Aug. 27, 2024

(30) Foreign Application Priority Data
Sep. 7, 2023 (CN) 202311152681.9

(51) Int. Cl. H05K 7/20

(52) U.S. Cl. CPC H05K 7/20272; H05K 7/20236; H05K 7/20781

(57) ABSTRACT

The present disclosure discloses a circulating submerged liquid cooling cabinet, including a cabinet body. An outer side of the cabinet body is provided with a control panel, and the cabinet body is hinged with a cabinet cover, which is provided with a quick opening mechanism. A lower end of the cabinet body is fixedly connected to a circulation box, where interior of the circulation box is fixedly connected to a surface cooler, and the interior of the circulation box is fixedly connected to a compressor, which is fixedly connected to a cooling pipe.

### CROSS REFERENCE TO RELATED APPLICATION

This application claims priority to Chinese Patent Application No. 202311152681.9, titled “CIRCULATING SUBMERGED LIQUID COOLING CABINET” and filed to the China National Intellectual Property Administration on Sep. 7, 2023, the entire contents of which are incorporated herein by reference.

### TECHNICAL FIELD

The present disclosure relates to the field of submerged liquid cooling cabinet technology, and more particularly, to a circulating submerged liquid cooling cabinet.

### BACKGROUND

According to patent application publication number CN 115955824A, a submerged liquid cooling cabinet is provided. The submerged liquid cooling cabinet includes a holding tank, a control component, and a server device. The holding tank includes a box body and a detachable cover body arranged on a top of the cover body, and a bottom surface and/or at least one side surface inside the box body is provided with a gas storage holder. The control component is tightly connected to the gas storage holder to control gas inflation or deflation of the gas storage holder. The server device is arranged in the box body, and the server device and the gas storage holder are arranged independently of each other. On the basis of meeting basic functions of the cabinet, the submerged liquid cooling cabinet can also ensure that the gas storage holder is filled with gas during normal operation such that a liquid level inside the box body rises, and that the gas in the gas storage holder is released during maintenance operation such that the liquid level drops. In this way, consumption of liquid used may be reduced, and the liquid is not easy to leak out, thereby reducing costs. However, during the use of the liquid cooling cabinet in the prior art, the liquid inside the cabinet is cooled through a refrigeration pipe, but temperature distribution of the refrigeration liquid is not uniform, which adversely affects cooling effects. Furthermore, the cabinet cover is not easy to open during use, which has an adverse effect on normal use. Therefore, the existing technologies need to be improved.

### SUMMARY

The present disclosure provides a circulating submerged liquid cooling cabinet, to solve a problem that it is uneven in refrigeration and inconvenient for opening a cabinet cover.

A circulating submerged liquid cooling cabinet provided by embodiments of the present disclosure includes a cabinet body. An outer side of the cabinet body is provided with a control panel, the cabinet body is hinged with a cabinet cover, and the cabinet cover is provided with a quick opening mechanism. A lower end of the cabinet body is fixedly connected to a circulation box, where interior of the circulation box is fixedly connected to a surface cooler, and the interior of the circulation box is fixedly connected to a compressor, which is fixedly connected to a cooling pipe. The interior of the circulation box is fixedly connected to a refrigeration box, and interior of the refrigeration box is fixedly connected to a circulation pump, where an output end of the circulation pump is fixedly connected to a connection pipe, and one end of the connection pipe is fixedly connected to a flow divider box. The flow divider box is fixedly connected to a plurality of evenly distributed sprinkler heads, and the flow divider box is fixedly connected to the cabinet body. Interior of the cabinet body is fixedly connected to a placing rack, and interior of the placing rack is provided with an electronic component. The circulation box is provided with a gas outlet, and the refrigeration box is fixedly connected to the cabinet body.

In the circulating submerged liquid cooling cabinet of the present disclosure, an outer side of the circulation box is fixedly connected to a filter net, and interior of the circulation box is fixedly connected to a fan, which can drive air inside the circulation box to flow.

In the circulating submerged liquid cooling cabinet of the present disclosure, the cooling pipe is fixedly connected to the refrigeration box, the compressor is fixedly connected to the refrigeration box, and the cooling pipe can refrigerate a liquid inside the refrigeration box.

In the circulating submerged liquid cooling cabinet of the present disclosure, the interior of the cabinet body is fixedly connected to a return pipe, where the return pipe is fixedly connected to the refrigeration box, and the return pipe can allow the liquid inside the cabinet body to flow into the refrigeration box.

In the circulating submerged liquid cooling cabinet of the present disclosure, the connection pipe is fixedly connected to the refrigeration box, the connection pipe is fixedly connected to the cabinet body, and the connection pipe can transport the cold liquid.

In the circulating submerged liquid cooling cabinet of the present disclosure, the quick opening mechanism includes a moving block, a fixing plate, a connecting rod, a connecting plate, a chamfer block, a sealing frame, and a spring. Interior of the cabinet cover is slidably connected to the moving block, an outer side of the moving block is fixedly connected to the connecting rod, and interior of the cabinet cover is fixedly connected to the fixing plate. One end of the connecting rod is fixedly connected to the connecting plate, where an outer side of the connecting plate is fixedly connected to the chamfer block, and interior of the cabinet body is fixedly connected to the sealing frame. An outer side of the connecting rod is fixedly provided with the spring, and the moving block can drive, by means of the connecting rod, to move the connecting plate.

In the circulating submerged liquid cooling cabinet of the present disclosure, one end of the spring is fixedly connected to the fixing plate, other end of the spring is fixedly connected to the moving block, and the spring can drive, by means of its elastic force, the moving block to automatically return to its original position.

In the circulating submerged liquid cooling cabinet of the present disclosure, the connecting plate is slidably connected to the cabinet cover, the chamfer block is slidably connected to the cabinet body, and the connecting plate can drive the chamfer block to move.

In the circulating submerged liquid cooling cabinet of the present disclosure, the sealing frame is slidably connected to the connecting plate, the sealing frame comes into contact with the chamfer block, and the chamfer block can limit the cabinet cover.

In the circulating submerged liquid cooling cabinet of the present disclosure, the sealing frame comes into contact with the cabinet cover, the connecting rod is slidably connected to the fixing plate, and the sealing frame can increase leak tightness between the cabinet cover and the cabinet body.

The technical solutions provided by the embodiments of the present disclosure may include following beneficial effects. The present disclosure designs a circulating submerged liquid cooling cabinet, structures such as a circulation pump, a flow divider box and a sprinkler head are additionally provided on the cabinet body. In the process of cooling electronic components, a coolant may be driven into the flow divider box by the circulation pump. Next, the coolant is sprayed into the cabinet body through the sprinkler head, such that the internal coolant may be stirred. In the process of stirring, the coolant may flow into a refrigeration box through a return pipe to cool the electronic components again. Thus, distribution of temperature of the coolant inside the cabinet body is more uniform by means of circulation.

Structures such as the connecting plate, the chamfer block and the moving block are additionally provided on the box cover. The chamfer block can be driven, by the elastic force of the spring, to slide onto the cabinet body to limit the cabinet cover. When it is required to open the cabinet cover, the chamfer block may be removed from the cabinet cover, such that the cabinet cover can be more conveniently opened.

### BRIEF DESCRIPTION OF THE DRAWINGS

To describe the technical solutions of the embodiments of the present disclosure more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a three-dimensional view of an overall structure according to the present disclosure;

FIG. 2 is an elevation cross-sectional view of FIG. 1;

FIG. 3 is an enlarged view of a structure of Part A in FIG. 2; and

FIG. 4 is an enlarged view of a structure of Part B in FIG. 2.

Reference numerals in the accompanying drawings:
cabinet body 1; control panel 2; cabinet cover 3; quick opening mechanism 4; circulation box; filter net 6; fan 7; surface cooler 8; compressor 9; cooling pipe 10; refrigeration box 11; circulation pump 12; connection pipe 13; flow divider box 14; sprinkler head 15; placing rack 16; electronic component 17; return pipe 18; gas outlet 19; moving block 41; fixing plate 42; connecting rod 43; connecting plate 44; chamfer block 45; sealing frame 46; and spring 47.

### DETAILED DESCRIPTION

Technical solutions in the embodiments of the present disclosure will be described clearly and completely below, in conjunction with the accompanying drawings in the embodiments of the present disclosure. Apparently, the described embodiments are some but not all of the embodiments of the present disclosure. All other embodiments obtained by a person of ordinary skill in the art based on the embodiments of the present disclosure without creative efforts shall fall within the protection scope of the present disclosure.

It should also be understood that the terms used in this specification of the present disclosure are only for the purpose of describing particular embodiments and are not intended to limit the present disclosure. As used in the specification and the appended claims of the present disclosure, the singular forms of “a”, “an” and “the” may be intended to include the plural forms, unless the context clearly indicates otherwise.

It should also be further understood that the term “and/or” used in the specification and the appended claims of the present disclosure refers to any combination of one or more of the relevantly listed items and all possible combinations, and includes these combinations.

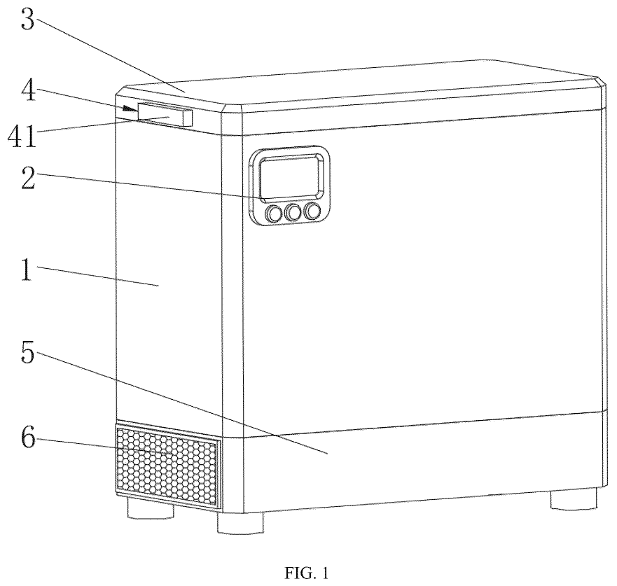

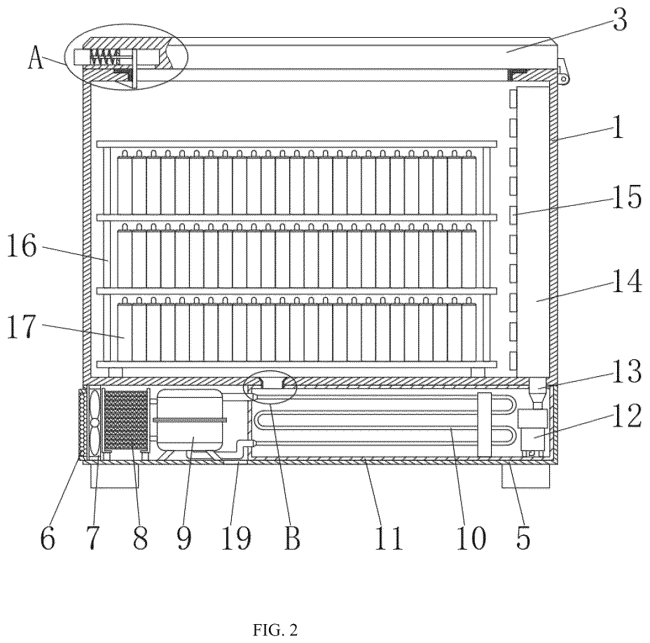

Referring to FIG. 1 and FIG. 2, the present disclosure discloses a circulating submerged liquid cooling cabinet, which includes a cabinet body 1. An outer side of the cabinet body 1 is provided with a control panel 2, the cabinet body 1 is hinged with a cabinet cover 3, and the cabinet cover 3 is provided with a quick opening mechanism 4. A lower end of the cabinet body 1 is fixedly connected to a circulation box 5, where interior of the circulation box 5 is fixedly connected to a surface cooler 8, and the interior of the circulation box 5 is fixedly connected to a compressor 9, which is fixedly connected to a cooling pipe 10. The interior of the circulation box 5 is fixedly connected to a refrigeration box 11, and interior of the refrigeration box 11 is fixedly connected to a circulation pump 12.

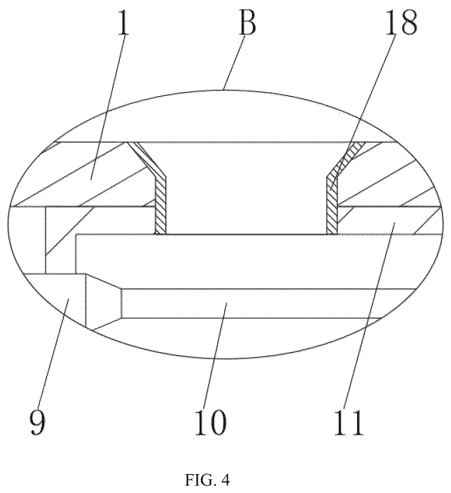

Referring to FIG. 1, FIG. 2 and FIG. 4, an output end of the circulation pump 12 is fixedly connected to a connection pipe 13, where one end of the connection pipe 13 is fixedly connected to a flow divider box 14. The flow divider box 14 is fixedly connected to a plurality of evenly distributed sprinkler heads 15, and the flow divider box 14 is fixedly connected to the cabinet body 1. Interior of the cabinet body 1 is fixedly connected to a placing rack 16, and interior of the placing rack 16 is provided with an electronic component 17. The circulation box 5 is provided with a gas outlet 19, and the refrigeration box 11 is fixedly connected to the cabinet body 1. An outer side of the circulation box 5 is fixedly connected to a filter net 6, and interior of the circulation box 5 is fixedly connected to a fan 7, which can drive air inside the circulation box 5 to flow. The cooling pipe 10 is fixedly connected to the refrigeration box 11, the compressor 9 is fixedly connected to the refrigeration box 11, and the cooling pipe 10 can refrigerate a liquid inside the refrigeration box 11. The interior of the cabinet body 1 is fixedly connected to a return pipe 18, where the return pipe 18 is fixedly connected to the refrigeration box 11, and the return pipe 18 can allow the liquid inside the cabinet body 1 to flow into the refrigeration box 11. The connection pipe 13 is fixedly connected to the refrigeration box 11, the connection pipe 13 is fixedly connected to the cabinet body 1, and the connection pipe 13 can transport the cold liquid.

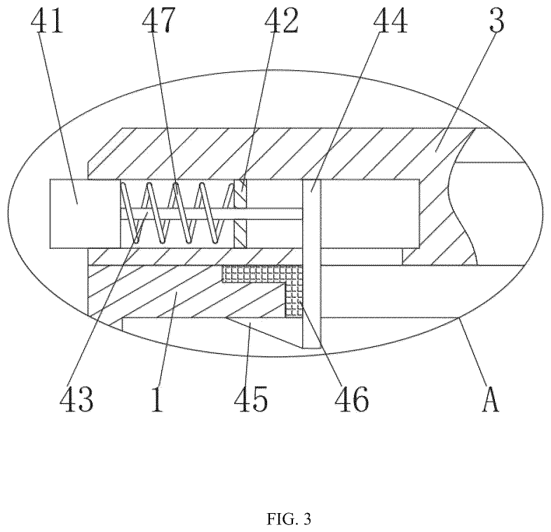

Referring to FIG. 1, FIG. 2 and FIG. 3, the quick opening mechanism 4 includes a moving block 41, a fixing plate 42, a connecting rod 43, a connecting plate 44, a chamfer block 45, a sealing frame 46, and a spring 47. Interior of the cabinet cover 3 is slidably connected to the moving block 41, an outer side of the moving block 41 is fixedly connected to the connecting rod 43, and interior of the cabinet cover 3 is fixedly connected to the fixing plate 42. One end of the connecting rod 43 is fixedly connected to the connecting plate 44, where an outer side of the connecting plate 44 is fixedly connected to the chamfer block 45, and interior of the cabinet body 1 is fixedly connected to the sealing frame 46. An outer side of the connecting rod 43 is fixedly provided with the spring 47, and the moving block 41 can drive, by means of the connecting rod 43, to move the connecting plate 44. One end of the spring 47 is fixedly connected to the fixing plate 42, other end of the spring 47 is fixedly connected to the moving block 41, and the spring 47 can drive, by means of its elastic force, the moving block 41 to automatically return to its original position. The connecting plate 44 is slidably connected to the cabinet cover 3, the chamfer block 45 is slidably connected to the cabinet body 1, and the connecting plate 44 can drive the chamfer block 45 to move. The sealing frame 46 is slidably connected to the connecting plate 44, the sealing frame 46 comes into contact with the chamfer block 45, and the chamfer block 45 can limit the cabinet cover 3. The sealing frame 46 comes into contact with the cabinet cover 3, the connecting rod 43 is slidably connected to the fixing plate 42, and the sealing frame 46 can increase leak tightness between the cabinet cover 3 and the cabinet body 1.

Specific implementation processes of the present disclosure are as follows. When in use, the cooling pipe 10 refrigerates a coolant inside the refrigeration box 11. After the liquid is refrigerated, the circulation pump 12 is started. The circulation pump 12 pumps the coolant with lower temperature into the flow divider box 14 through the connection pipe 13. Next, the coolant is sprayed into the cabinet body 1 through the sprinkler heads 15 on the flow divider box 14, such that the internal coolant may be stirred, and thus temperature of the coolant is more uniform. In the process of stirring, the coolant may flow back into the refrigeration box 11 through the return pipe 18 to cool the electronic components 17 again. Thus, the electronic components 17 can be cooled more uniformly.

When it is required to open the cabinet cover 3, the moving block 41 is pushed, such that the moving block 41 drives, by means of the connecting rod 43, the bevel block 45 on the connecting plate 44 to move, and compresses the spring 47. When the bevel block 45 gets away from the cabinet body 1, the limit of the cabinet cover 3 can be released, and thus the cabinet cover 3 can be easily opened.

The preceding descriptions are merely specific embodiments of the present disclosure, but the protection scope of the present disclosure is not limited thereto. Any equivalent modifications or replacements easily conceivable to a person of skilled in the art within the technical scope disclosed in the present disclosure shall fall within the protection scope of the present disclosure. Therefore, the protection scope of the present disclosure shall be subject to that of the claims.

What is claimed is:

1. A circulating submerged liquid cooling cabinet comprising a cabinet body, wherein an outer side of the cabinet body is provided with a control panel, the cabinet body is hinged with a cabinet cover, the cabinet cover is provided with a quick opening mechanism, a lower end of the cabinet body is fixedly connected to a circulation box, interior of the circulation box is fixedly connected to a surface cooler, and the interior of the circulation box is fixedly connected to a compressor, the compressor is fixedly connected to a cooling pipe, the interior of the circulation box is fixedly connected to a refrigeration box, interior of the refrigeration box is fixedly connected to a circulation pump, an output end of the circulation pump is fixedly connected to a connection pipe, one end of the connection pipe is fixedly connected to a flow divider box, the flow divider box is fixedly connected to a plurality of evenly distributed sprinkler heads, the flow divider box is fixedly connected to the cabinet body, interior of the cabinet body is fixedly connected to a placing rack, interior of the placing rack is provided with an electronic component, the circulation box is provided with a gas outlet, and the refrigeration box is fixedly connected to the cabinet body.

2. The circulating submerged liquid cooling cabinet according to claim 1, wherein an outer side of the circulation box is fixedly connected to a filter net, and interior of the circulation box is fixedly connected to a fan.

3. The circulating submerged liquid cooling cabinet according to claim 1, wherein the cooling pipe is fixedly connected to the refrigeration box, and the compressor is fixedly connected to the refrigeration box.

4. The circulating submerged liquid cooling cabinet according to claim 1, wherein the interior of the cabinet body is fixedly connected to a return pipe, and the return pipe is fixedly connected to the refrigeration box.

5. The circulating submerged liquid cooling cabinet according to claim 1, wherein the connection pipe is fixedly connected to the refrigeration box, and the connection pipe is fixedly connected to the cabinet body.

6. The circulating submerged liquid cooling cabinet according to claim 1, wherein the quick opening mechanism comprises a moving block, a fixing plate, a connecting rod, a connecting plate, a chamfer block, a sealing frame, and a spring; interior of the cabinet cover is slidably connected to the moving block, an outer side of the moving block is fixedly connected to the connecting rod, interior of the cabinet cover is fixedly connected to the fixing plate, one end of the connecting rod is fixedly connected to the connecting plate, an outer side of the connecting plate is fixedly connected to the chamfer block, interior of the cabinet body is fixedly connected to the sealing frame, and an outer side of the connecting rod is fixedly provided with the spring.

7. The circulating submerged liquid cooling cabinet according to claim 6, wherein one end of the spring is fixedly connected to the fixing plate, and other end of the spring is fixedly connected to the moving block.

8. The circulating submerged liquid cooling cabinet according to claim 6, wherein the connecting plate is slidably connected to the cabinet cover, and the chamfer block is slidably connected to the cabinet body.

9. The circulating submerged liquid cooling cabinet according to claim 6, wherein the sealing frame is slidably connected to the connecting plate, and the sealing frame comes into contact with the chamfer block.

10. The circulating submerged liquid cooling cabinet according to claim 6, wherein the sealing frame comes into contact with the cabinet cover, and the connecting rod is slidably connected to the fixing plate.
